(19) United States
(12) Patent Application Publication
(10) Pub. No.: US 2013/0179745 A1
(43) Pub. Date: Jul. 11, 2013

(54) TEST INTERFACE CIRCUIT FOR INCREASING TESTING SPEED

(71) Applicant: Chiu-Huang Huang, Hsinchu County (TW)

(72) Inventor: Chiu-Huang Huang, Hsinchu County (TW)

(73) Assignee: NOVATEK MICROELECTRONICS CORP., Hsinchu (TW)

(21) Appl. No.: 13/541,639

(22) Filed: Jul. 3, 2012

(30) Foreign Application Priority Data
Jan. 6, 2012 (TW) 101100656

(51) Int. Cl. G01R 31/3177

(52) U.S. Cl. 714/733; 714/E11.155

(57) ABSTRACT

A test interface circuit couplable between a source driver and test equipment is disclosed. The test interface circuit includes a plurality of test interface modules and a logic circuit. Each of the test interface modules receives an output signal from one of a plurality of output pins of the source driver, judges whether the received output signal falls in a specified range or not, and generates a deviation signal accordingly. The logic circuit generates a deviation test output signal according to the deviation signals generated by the test interface modules.

### CROSS-REFERENCE TO RELATED APPLICATION

This application claims the priority benefit of Taiwan application serial no. 101100656, filed on Jan. 6, 2012. The entirety of the above-mentioned patent application is hereby incorporated by reference herein and made a part of this specification.

### BACKGROUND OF THE INVENTION

1. Field of the Invention

The present invention generally relates to a test interface circuit, in particular, to a test interface circuit of a source driver.

2. Description of Related Art

With the popularization of the consumer electronic products, for displays in recent years, the size of the screen and the display resolution are both continuously increased year after year. Therefore, the number of pins of a source driver for driving the display is increased correspondingly.

In the prior art, when the source driver with the high number of pins is tested, since it is required to calculate whether output signals of a plurality of pins meet the specification requirements or not, used test equipment needs to have the capabilities of supporting the test of the high number of pins and rapidly calculating a plurality of output signals. That is to say, due to the multi-pin characteristic of the source driver, when the source driver is tested, expensive high-level test equipment is unavoidably used. Besides, in the case that the number of pins of the source driver is ever increased, only a limited number of source drivers can be tested each time even with the high-level test equipment. Accordingly, when a mass production test for the source driver is performed, an excessively lengthy test time is required, and the problems of an increased test cost and insufficient productivity are derived.

### SUMMARY OF THE INVENTION

Accordingly, a test interface circuit is provided, capable of effectively improving the speed of test of a source driver to reduce the test cost.

In an embodiment of the present invention, the test interface circuit is couplable between the source driver and test equipment. The test interface includes a plurality of test interface modules and a logic circuit. Each of the test interface modules receives an output signal from one of a plurality of output pins of the source driver, judges whether the received output signal falls in a specified range or not, and generates a deviation signal accordingly. The logic circuit generates a deviation test output signal according to the deviation signals generated by the test interface modules.

In an embodiment of the present invention, the test interface module further includes a function of calculating an average value of the output signals of the output pins of the source driver.

In an embodiment of the present invention, the logic circuit includes one or more AND gates, coupled in series or in parallel between a plurality of deviation signal input ends and a deviation signal output end, so as to receive the deviation signals at the deviation signal input ends and output the deviation test output signal at the deviation signal output end.

In an embodiment of the present invention, the specified range is between a higher specified limit and a lower specified limit. Each of the test interface modules compares the output signal of the corresponding output pin thereof with the higher specified limit and the lower specified limit respectively to generate the deviation signal.

In an embodiment of the present invention, the test interface module includes a first comparison circuit, a second comparison circuit, and an AND gate. The first comparison circuit receives the output signal of each of the output pins corresponding to each of the test interface modules, and compares the output signal with the higher specified limit to generate a first comparison output signal. The second comparison circuit receives the output signal of each of the output pins corresponding to each of the test interface modules, and compares the output signal with the lower specified limit to generate a second comparison output signal. The AND gate is coupled to the first comparator and the second comparator to generate the deviation signal according to the first comparison signal and the second comparison signal.

In an embodiment of the present invention, the test interface module further includes a switch and a hold capacitor. The switch includes a first end coupled to each of the output pins corresponding to each of the test interface modules. The switch further includes a second end coupled to the first comparison circuit and the second comparison circuit. The hold capacitor is coupled to the second end of the switch and used for holding a voltage level of each of the output signals.

In an embodiment of the present invention, the test interface module further includes a switched capacitor circuit. The switched capacitor circuit is coupled between each of the output pins corresponding to each of the test interface modules and an average signal output end and used for transmitting the output signal of the corresponding output pin to the average signal output end.

In an embodiment of the present invention, the average signal output ends of the test interface modules are collectively coupled to an average signal generating end of the test interface circuit.

In an embodiment of the present invention, the switched capacitor circuit of each of the test interface modules includes a first switch, a hold capacitor, and a second switch. A first end of the first switch is coupled to the output pin corresponding to each of the test interface modules. The hold capacitor is coupled to a second end of the first switch. The second switch is coupled between the second end of the first switch and the average signal output end of each of the test interface modules.

Based on the above, the plurality of test interface modules judges whether the output signals of the output pins of the source driver fall in the specified range or not, to generate the deviation signal, and the deviation test output signal is generated according to the deviation signals. The test interface modules are disposed between the source driver and the test equipment to perform test actions being originally only capable of being performed by high-level test equipment. In this way, the source driver can be tested through low-level test equipment, so as to effectively reduce the test cost.

In order to make the features and advantages of the present invention clearer and more comprehensible, the present invention is described in detail below with reference to embodiments and the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an embodiment of a test interface circuit 100 according to the present invention.

FIG. 2 is a schematic diagram of an implementation manner of a test interface module 111 according to an embodiment of the present invention.

FIG. 3A and FIG. 3B are respectively schematic diagrams of implementation manners of a logic circuit 120 according to an embodiment of the present invention.

FIG. 4 illustrates an implementation example of a test interface circuit according to the present invention.

FIG. 5 illustrates another implementation example of a test interface circuit according to the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts. In addition, “coupled” as used herein is defined as directly connected, or indirectly connected through one or more intermediary devices or means. The term “signal” means at least one signal such as current signal, voltage signal, electromagnetic wave signal, or data signal.

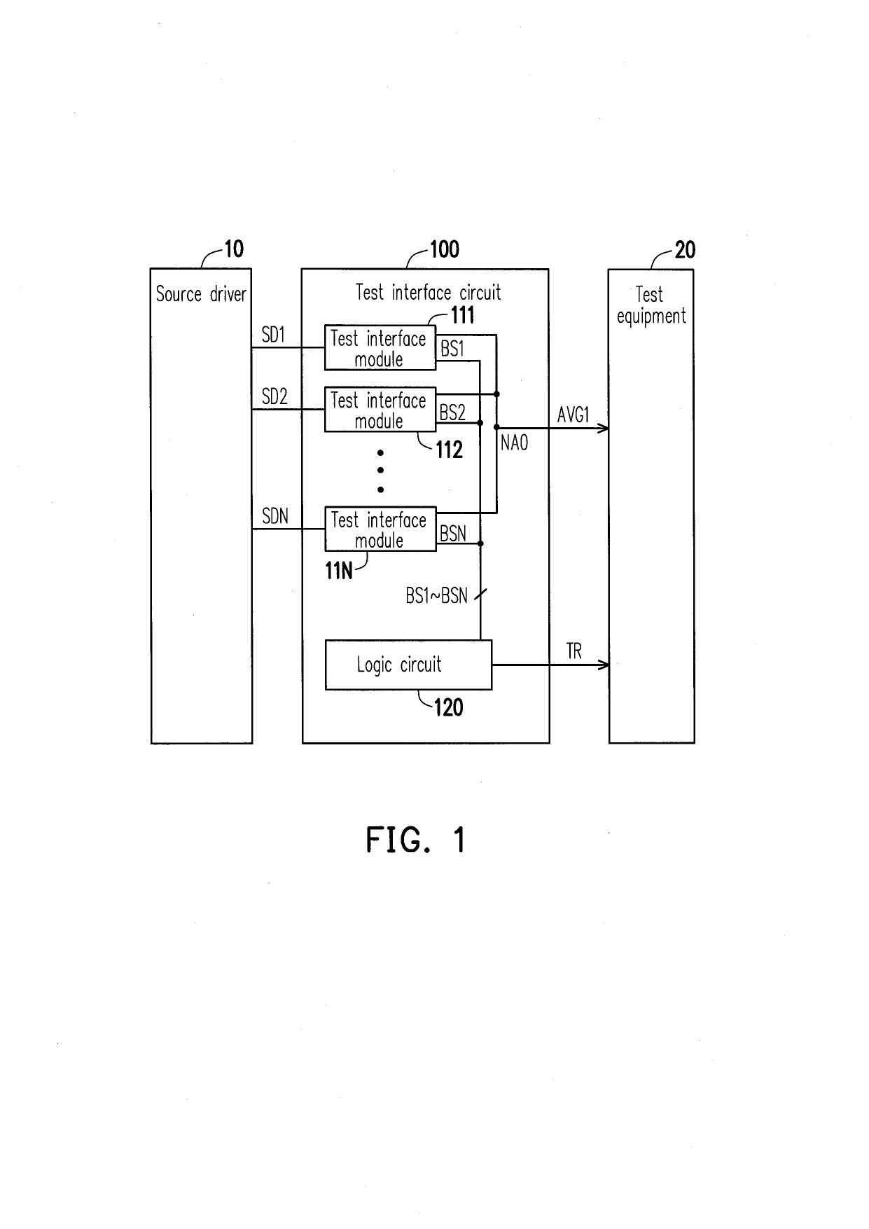

FIG. 1 is a schematic diagram of an embodiment of a test interface circuit 100 according to the present invention. Referring to FIG. 1, the test interface circuit 100 may be implemented as an integrated circuit and is couplable between test equipment 20 and a source driver 10 during a test. As shown in FIG. 1, the test interface circuit 100 includes a plurality of test interface modules 111 to 11N and a logic circuit 120. As known by persons of ordinary skill in the art, the source driver 10 may include a plurality of drive circuits and generate a plurality of output signals for driving a display.

In this embodiment, each of the test interface modules 111 to 11N receives a plurality of output signals SD1 to SDN generated by a plurality of output pins of the source driver 10. The test interface modules 111 to 11N respectively judge whether the received output signals SD1 to SDN fall in a preset specified range or not, so as to judge whether the drive circuit to which the pin of the source driver 10 connected to each of the test interface modules 111 to 11N belongs is normal or not. Each of the test interface modules 111 to 11N generates one of deviation signals BS1 to BSN according to whether the drive circuit to which the pin of the source driver 10 connected to each of the test interface modules 111 to 11N belongs is normal or not.

It should be noted that, the specified range may be a numerical range preset by a test engineer. That is to say, the specified range may include a higher specified limit and a lower specified limit. The test interface modules 111 to 11N respectively judge whether the received output signals SD1 to SDN are not greater than (or less than) the higher specified limit and not less than (or greater than) the lower specified limit, and generate the deviation signals BS1 to BSN according to judgment results. In brief, the deviation signals BS1 to BSN each may include two states, that is, the output signals SD1˜SDN are deviated (exceed the specified range) or not deviated (not exceed the specified range).

After being set, the specified range may be inputted into the test equipment 20 by the test engineer, and the test equipment 20 transmits the specified range to the test interface modules 111 to 11N. In this way, the test interface modules 111 to 11N can generate the deviation signals BS1 to BSN according to the specified range and the output signals SD1 to SDN.

The logic circuit 120 is coupled to the test interface modules 111 to 11N. The logic circuit 120 receives the deviation signals BS1 to BSN generated by all the test interface modules 111 to 11N and generates a deviation test output signal TR according to the deviation signals BS1 to BSN.

In some embodiments, since it is required in the test requirement of the source driver that, the output signals SD1 to SDN generated by all the drive circuits included in the source driver 10 must completely meet the requirement of the specified range, only when all the deviation signals BS1 to BSN indicate that the corresponding output signals SD1 to SDN thereof are not deviated, the source driver 10 is a good die. In contrast, if at least one of the deviation signals BS1 to BSN indicates that one of the output signals SD1 to SDN corresponding to the at least one deviation signal is deviated, the source driver 10 is a fail die.

The logic circuit 120 generates the deviation test output signal TR according to the foregoing requirement. Briefly speaking, if at least one of the deviation signals BS1 to BSN indicates that one of the output signals SD1 to SDN corresponding to the at least one deviation signal is deviated, the logic circuit 120 generates a deviation test output signal TR indicating that the source driver 10 is a fail die. In contrast, if none of the deviation signals BS1 to BSN indicates that one of the output signals SD1 to SDN is deviated, the logic circuit 120 generates a deviation test output signal TR indicating that the source driver 10 is a good die.

Furthermore, the test interface circuit 100 transmits the generated deviation test output signal TR to the test equipment 20. According to the deviation test output signal TR, the test equipment 20 can identify whether all the drive circuits of the source driver 10 can correctly generate the output signals SD1 to SDN.

Incidentally, when the source driver 10 is tested, the source driver 10 may also generate different output signals SD1 to SDN according to different gray scale values, and different deviation test output signals TR are generated according to the output signals SD1 to SDN corresponding to the gray scale values.

In addition to the foregoing functions, preferably, the test interface circuit 100 may also calculate an average value AVG1 of the output signals SD1 to SDN generated by the output pins of the source driver 10. The test interface circuit 100 transmits the calculated average value AVG1 of the output signals SD1 to SDN to the test equipment 20. In this way, the test equipment 20 can effectively identify an offset (a difference between the average value AVG1 and an ideal average value) of the output signals SD1 to SDN generated by the drive circuits of the source driver 10, and generate an offset test result accordingly.

Therefore, when the source driver 10 is tested, the source driver 10 may also generate different output signals SD1 to SDN according to different gray scale values, and different average values AVG1 are generated accordingly. The test equipment 20 can easily identify the offsets generated according to the gray scale values corresponding to the output signals SD1 to SDN, and determine whether the tested source driver 10 is a good die or a fail die accordingly.

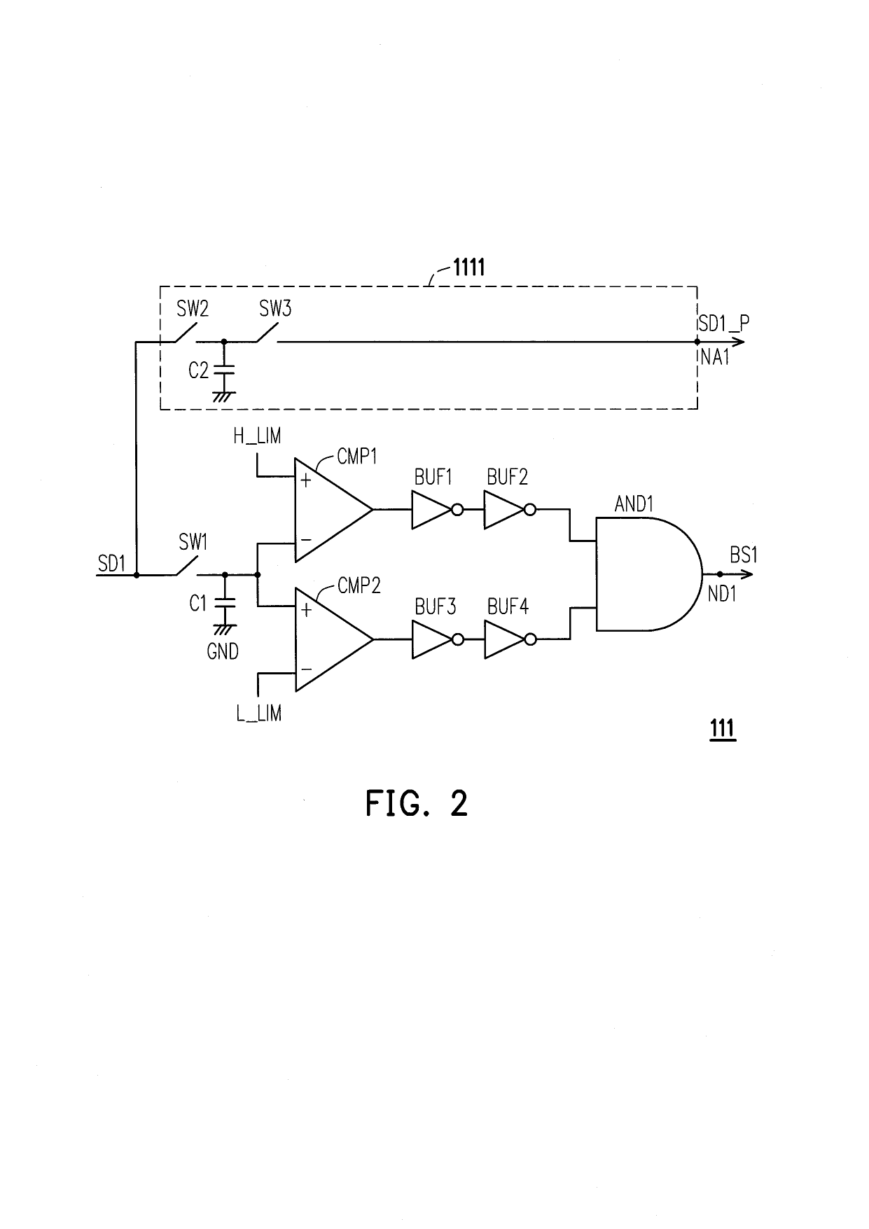

FIG. 2 is a schematic diagram of an implementation manner of a test interface module 111 according to an embodiment of the present invention. Referring to FIG. 2, the test interface module 111 includes comparison circuits CMP1 and CMP2, an AND gate AND 1, a switched capacitor circuit 1111, a hold capacitor C1, and a switch SW1. One end of the switch SW1 is coupled to the source driver to receive an output signal SD1 generated by the source driver. The hold capacitor C1 is connected in series between the other end, not receiving the output signal SD1, of the switch SW1 and a reference voltage (for example, a grounding voltage GND). One input end of the comparison circuit CMP1 and one input end of the comparison circuit CMP2 are collectively coupled to a common coupling point of the switch SW1 and the hold capacitor C1, and the other input ends of the comparison circuits CMP1 and CMP2 respectively receive a higher specified limit H_LIM and a lower specified limit L_LIM. The AND gate AND 1 receives outputs of the comparison circuits CMP1 and CMP2 and generates a deviation signal BS1 accordingly. The switched capacitor circuit 1111 is coupled between the output pin of the output signal SD1 of the source driver corresponding to the test interface module 111 and an average signal output end NA1. The average signal output end of the switched capacitor circuit 1111 and average signal output ends of other test interface modules are collectively coupled to an average signal generating end NAO for generating an average signal AVG1.

In the overall actuation, first, the switch SW1 is turned on, the output signal SD1 is transmitted to the hold capacitor C1, and a voltage level of the output signal SD1 is saved in the hold capacitor C1. Then, the switch SW1 may be turned off, the comparison circuits CMP1 and CMP2 respectively compare the voltage level of the output signal SD1 with the higher specified limit H_LIM and the lower specified limit L_LIM. Comparison results of the comparison circuits CMP1 and CMP2 are respectively transmitted to the AND gate AND1 through buffers BUF1 to BUF2 and BUF3 to BUF4. The AND gate AND1 generates the deviation signal BS1 according to the comparison results of the comparison circuits CMP1 and CMP2.

In this implementation manner, when the voltage level of the output signal SD1 is between the higher specified limit H_LIM and the lower specified limit L_LIM, the comparison circuits CMP1 and CMP2 generate logic high-level comparison results and output the logic high-level comparison results to the AND gate AND1. Therefore, the AND gate AND1 also generates a logic high-level deviation signal BS1 for indicating that the drive circuit generating the output signal SD1 is a good die. In contrast, when the voltage level of the output signal SD1 falls outside of the higher specified limit H_LIM and the lower specified limit L_LIM (is greater than the higher specified limit H_LIM and less than the lower specified limit L_LIM), one of the comparison circuits CMP1 and CMP2 generates a logic low-level comparison result. Therefore, the AND gate AND1 also generates a logic low-level deviation signal BS1 for indicating that the drive circuit generating the output signal SD1 is a fail die.

As regards the switched capacitor circuit 1111, first, a switch SW2 is turned on and a switch SW3 is turned off. At this time, the voltage level of the output signal SD1 is held in a capacitor C2. Then, the switch SW2 is turned off and the switch SW3 is turned on, and the switched capacitor circuit 1111 transmits the voltage level SD1_P held in the capacitor C2 to switched capacitor circuits of other test interface modules. In the case that the switched capacitor circuits (including capacitance values thereof) in all the test interface modules are the same, an endpoint (that is, the average signal generating end NAO for generating the average signal AVG1 in FIG. 1), through which all the switched capacitor circuits are connected to one another, generates an average value of all the output signals SD1 to SDN of the source driver 10.

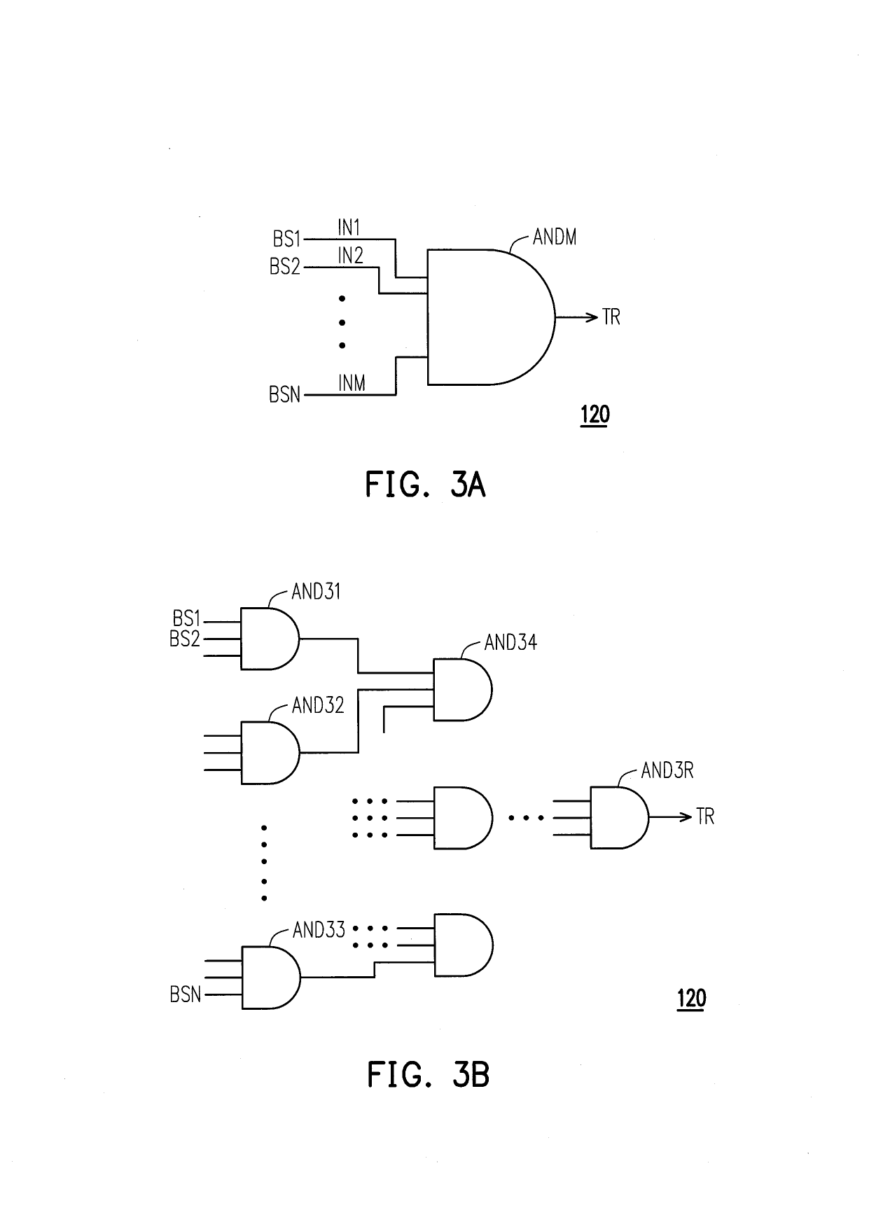

FIG. 3A and FIG. 3B are respectively schematic diagrams of implementation manners of the logic circuit 120 according to an embodiment of the present invention. Referring to FIG. 3A first, the logic circuit 120 is constructed by a multi-input AND gate ANDM. The AND gate ANDM includes a plurality of input ends IN1 to INM, where each of the input ends is coupled to each test interface module to receive the deviation signals BS1˜BSN generated by the test interface modules. The AND gate ANDM generates the deviation test output signal TR according to the received plurality of deviation signals BS1 to BSN. Here, the number (that is, M) of the input ends of the AND gate ANDM may be the same as the number (that is, N) of test interface modules.

In FIG. 3B, the logic circuit 120 is constructed by a plurality of tri-input-end AND gates AND31 to AND3R (R is a positive integer). In this implementation manner, the AND gates AND31 to AND3R are divided into a plurality of levels. AND gates (for example, the AND gates AND31 to AND33) of the same level are connected in parallel. AND gates (for example, the AND gate AND31 and the AND gate AND34) on adjacent levels are interconnected in series. The AND gates AND31 to AND33 belonging to the first level receive the deviation signals BS1 to BSN. All the AND gates AND31 to AND3R perform a logic operation of AND on the deviation signals BS1 to BSN and generate the deviation test output signal TR accordingly.

In the implementation manner of FIG. 3B, the number of input ends of the AND gate may be changed randomly and is not limited to three. However, when the AND gates with a different number of input ends are applied to implement the logic circuit 120, a different number and stage of AND gates may be required, which is well-known to persons of ordinary skill in the art and is not described here in detail.

A plurality of actual implementation examples of the test interface circuit of the present invention is provided in the following, so that persons of ordinary skill in the art can understand the present invention more clearly and implement the present invention.

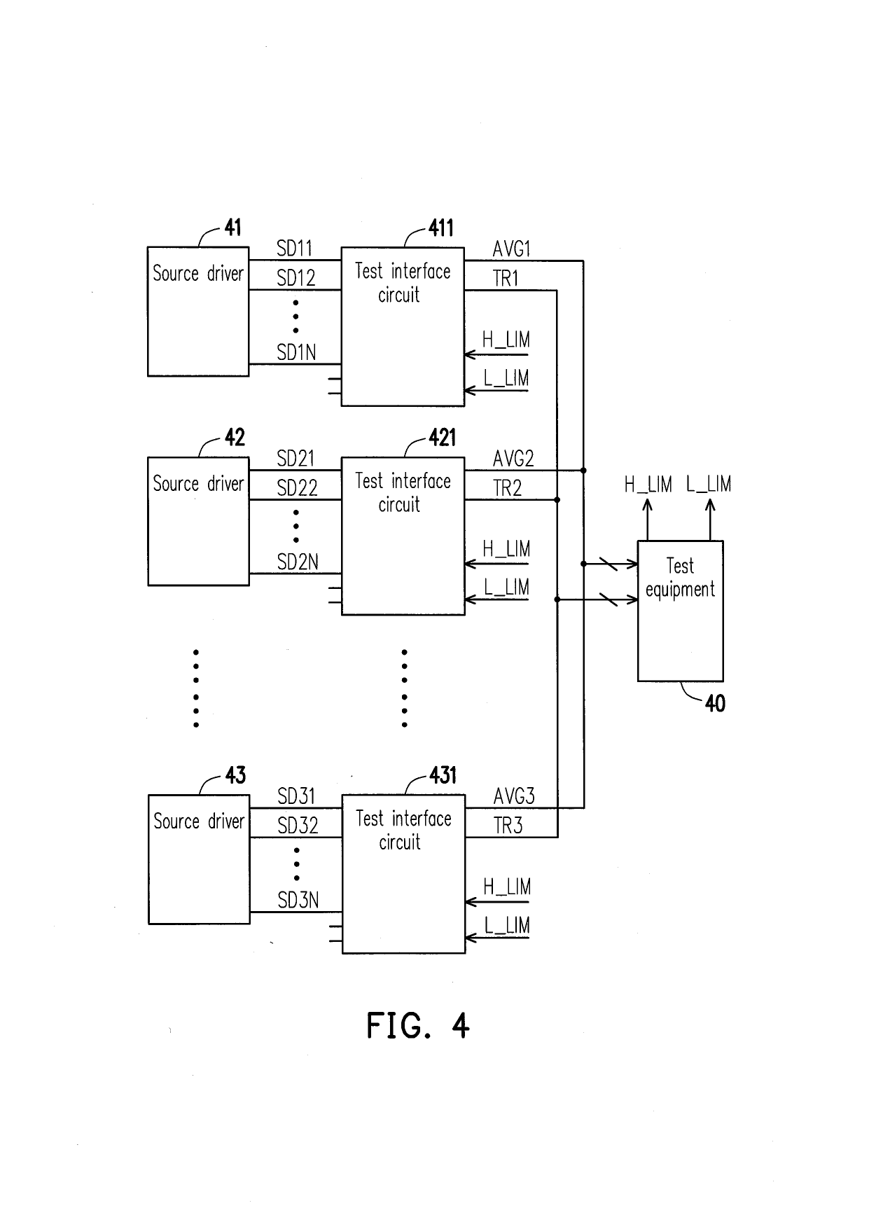

FIG. 4 illustrates an implementation example of a test interface circuit according to the present invention. Referring to FIG. 4, test equipment 40 is connected to a plurality of test interface circuits 411 to 431 and can test a plurality of source drivers 41 to 43 synchronously. For the test interface circuits 411 to 431, the number of test interface modules included in each of the test interface circuits 411 to 431 is greater than or equal to the total number of output pins of each of the source drivers 41 to 43. Therefore, the test interface circuit 411 is connected to the source driver 41 to receive output signals SD11 to SD1N, the test interface circuit 421 is connected to the source driver 42 to receive output signals SD21 to SD2N, and the test interface circuit 431 is connected to the source driver 43 to receive output signals SD31 to SD3N.

The test interface circuits 411 to 431 can synchronously compare the received output signals SD11 to SD3N with a higher specified limit H_LIM and a lower specified limit L_LIM, and respectively generate deviation test output signals TR1 to TR3 corresponding to the source drivers 41 to 43 and average values AVG1 to AVG3 corresponding to the source drivers 41 to 43 to respectively generate offset test results corresponding to the source drivers 41 to 43. In this way, the plurality of source drivers 41 to 43 can be tested synchronously.

Incidentally, the higher specified limit H_LIM and the lower specified limit L_LIM can be set on the test equipment 40 by a test engineer, and transmitted to the test interface circuits 411 to 431 by the test equipment 40.

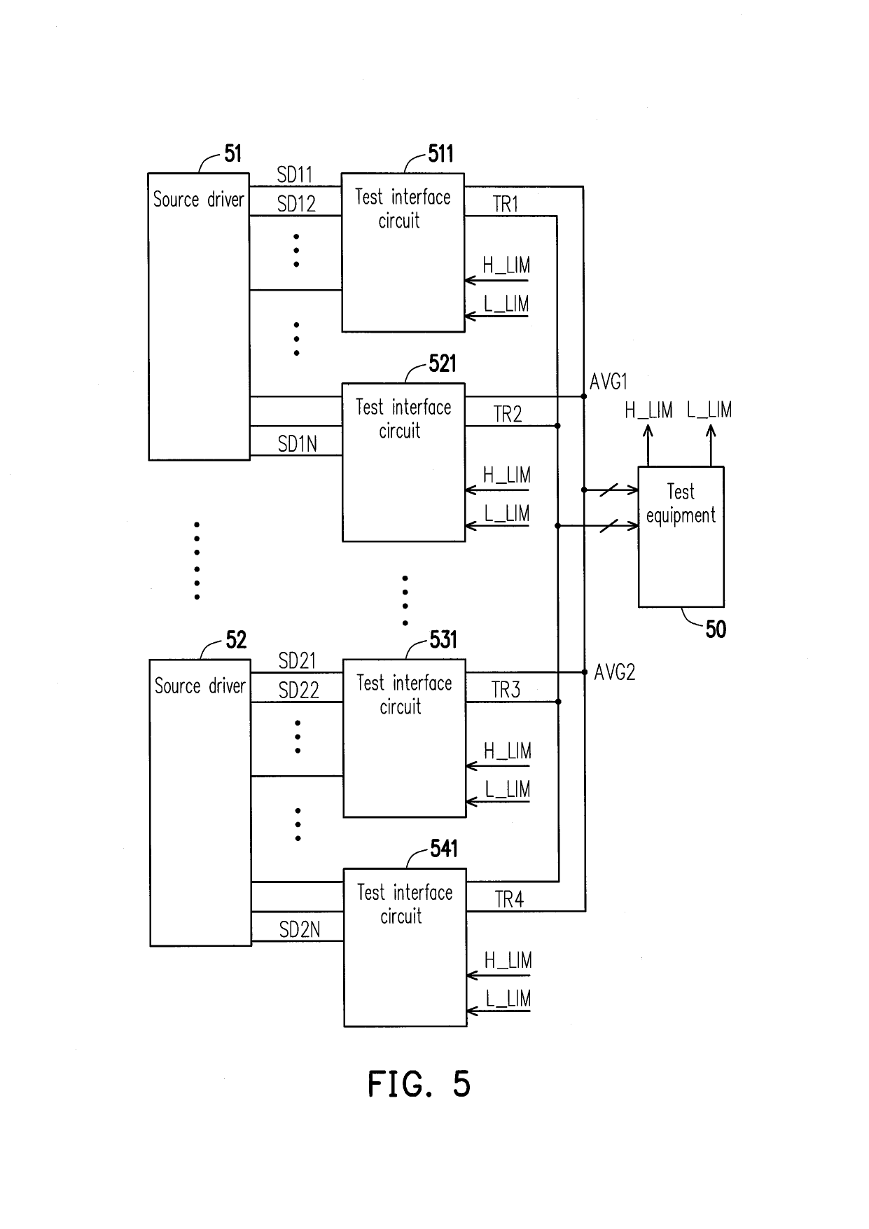

FIG. 5 illustrates another implementation example of a test interface circuit according to the present invention. Referring to FIG. 5, test equipment 50 is connected to a plurality of test interface circuits 511 to 541 and can test a plurality of source drivers 51 to 52 synchronously. For the test interface circuits 511 to 541, the number of test interface modules within each of the test interface circuits 511 to 541 is less than the total number of output pins of each of the source drivers 51 to 52. That is to say, the source drivers 51 and 52 need to be connected to two test interface circuits 511 and 521 and two test interface circuits 531 and 541 respectively. The test interface circuits 511 and 521 test output signals SD11 to SD1N generated by the source driver 51 and generate deviation test output signals TR1 and TR2 and an average value AVG1. The test interface circuits 531 and 541 test output signals SD21 to SD2N generated by the source driver 52 and generate deviation test output signals TR3 and TR4 and an average value AVG2. The deviation test output signals TR1 to TR4 and the average values AVG1 and AVG2 can be synchronously provided to the test equipment 50 for judgment. In this way, the plurality of source drivers 51 to 52 can be tested synchronously.

In sum, in the embodiments, the test interface circuit is used to provide the plurality of test interface modules. The test interface modules can be used to compare the output signals of the plurality of output pins of the source driver and provide the deviation test output signal to the test equipment accordingly. In this way, the test equipment may not need to perform the operation on the output signal of each of the output pins of the source driver, and only needs to judge whether the source driver is good according to the deviation test output signal in a digital format, so the operation time of the test equipment is effectively reduced, and even low-level test equipment can complete the test of the source driver. As a result, the embodiments can effectively reduce the test cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A test interface circuit, couplable between a source driver and a test equipment, comprising:
a plurality of test interface modules, each receiving an output signal from one of a plurality of output pins of the source driver, and judging whether the received output signal falls in a specified range or not, so as to generate a deviation signal; and
a logic circuit, for generating a deviation test output signal according to the deviation signals generated by the test interface modules.

2. The test interface circuit according to claim 1, wherein the test interface modules further calculate an average value of the output signals of the output pins of the source driver.

3. The test interface circuit according to claim 1, wherein the logic circuit comprises one or more AND gates coupled in series or in parallel between a plurality of deviation signal input ends and a deviation signal output end, and the logic circuit receives the deviation signals at the deviation signal input ends and output the deviation test output signal at the deviation signal output end.

4. The test interface circuit according to claim 1, wherein the specified range is between a higher specified limit and a lower specified limit, and each of the test interface modules compares the output signal of the corresponding output pin thereof with the higher specified limit and the lower specified limit respectively to generate the deviation signal.

5. The test interface circuit according to claim 4, wherein each of the test interface modules comprises:
a first comparison circuit, for receiving the output signal of each of the output pins corresponding to each of the test interface modules and comparing the output signal with the higher specified limit to generate a first comparison output signal;
a second comparison circuit, for receiving the output signal of each of the output pins corresponding to each of the test interface modules and comparing the output signal with the lower specified limit to generate a second comparison output signal; and
an AND gate, coupled to the first comparator and the second comparator to generate the deviation signal according to the first comparison signal and the second comparison signal.

6. The test interface circuit according to claim 5, wherein each of the test interface modules further comprises:
a switch, having a first end coupled to each of the output pins corresponding to the each of the test interface modules and a second end coupled to the first comparison circuit and the second comparison circuit; and
a hold capacitor, coupled to the second end of the switch and used for holding a voltage level of each of the output signals.

7. The test interface circuit according to claim 2, wherein each of the test interface modules further comprises:
a switched capacitor circuit, coupled between each of the output pins corresponding to each of the test interface modules and an average signal output end, and used for transmitting the output signal of the corresponding output pin to the average signal output end.

8. The test interface circuit according to claim 7, wherein the average signal output ends of the test interface modules are collectively coupled to an average signal generating end of the test interface circuit.

9. The test interface circuit according to claim 7, wherein the switched capacitor circuit of each of the test interface modules comprises:
a first switch, having a first end coupled to the output pin corresponding to each of the test interface modules;
a hold capacitor, coupled to a second end of the first switch; and
a second switch, coupled between the second end of the first switch and the average signal output end of each of the test interface modules.

10. A test interface circuit, comprising:
a plurality of test interface modules, each receiving an output signal from one of a plurality of output pins of a source driver, judging whether or not the received output signal falls in a specified range between a higher specified limit and a lower specified limit, so as to generate a deviation signal, and calculating an average value of the output signals of the output pins of the source driver; and
a logic circuit, for generating a deviation test output signal according to the deviation signals generated by the test interface modules.
